(19) United States
(12) Patent Application Publication
(10) Pub. No.: US 2009/0191669 A1
(43) Pub. Date: Jul. 30, 2009

(54) METHOD OF ENCAPSULATING AN ELECTRONIC COMPONENT

(76) Inventor: Yu-Kang PENG, Taipei City (TW)

Correspondence Address: SINORICA, LLC, 2275 Research Blvd., Suite 500, ROCKVILLE, MD, 20850, US

(21) Appl. No.: 12/019,126

(22) Filed: Jan. 24, 2008

(51) Int. Cl. H01L 21/56

(52) U.S. Cl. 438/119; 257/E21.502

(57) ABSTRACT

A procedure of packaging an electronic component is provided, comprising the following steps: step A for mount at which a conductor and a chip are temporarily mounted on a carrier removable, and next step B for encapsulation at which the conductor and the chip are encapsulated with colloid and mounted and then removed from the carrier so that the chipset after modeled without any substrate may be mounted for decreasing the costs of substrate use and design and the probability of damage of the substrate an chip due to the thermal expansion and increasing the yield factor of a finished product.

### BACKGROUND OF THE INVENTION

1. Field of the Invention

This invention relates to a encapsulating method and particularly to a method of encapsulating an electronic component without any substrate into a unit.

2. Description of Related Art

With reference to FIG. 1, in a conventional method of encapsulating a semiconductor, an adhesive resin 2 is coated on a lead frame 1, a die 3 is connected and fixed onto the lead frame 1, a bonding wire 4 is used to connect the lead frame 1 conductively to the die 3, and finally a resin 5 is used for encapsulation, thereby an integrated circuit being formed. However, in the conventional method of encapsulation, materials are different in the coefficient of heat expansion, and thus the encapsulated component is easily damaged when being heated to cause a stress strain.

Consequently, because of the technical defects of described above, the applicant keeps on carving unflaggingly through wholehearted experience and research to develop the present invention, which can effectively improve the defects described above.

### SUMMARY OF THE INVENTION

In this invention, a procedure of encapsulating an electronic component is provided, comprising at least the following steps: step A for mount at which a conductor and a chip are temporarily mounted on a carrier movable, and next step B for encapsulation at which the conductor and the chip are adhered with colloid and mounted and then removed from the carrier.

In this invention, the procedure of encapsulation the electronic component is provided, in which after being encapsulated, the chip is formed and mounted with the colloid but no carrier; the costs of substrate use and design may be decreased and no consideration of heat expansion between the substrate and the chip is made.

### BRIEF DESCRIPTION OF THE DRAWINGS

FIG. 1 is a schematic view illustrating the flow of of a conventional chip;

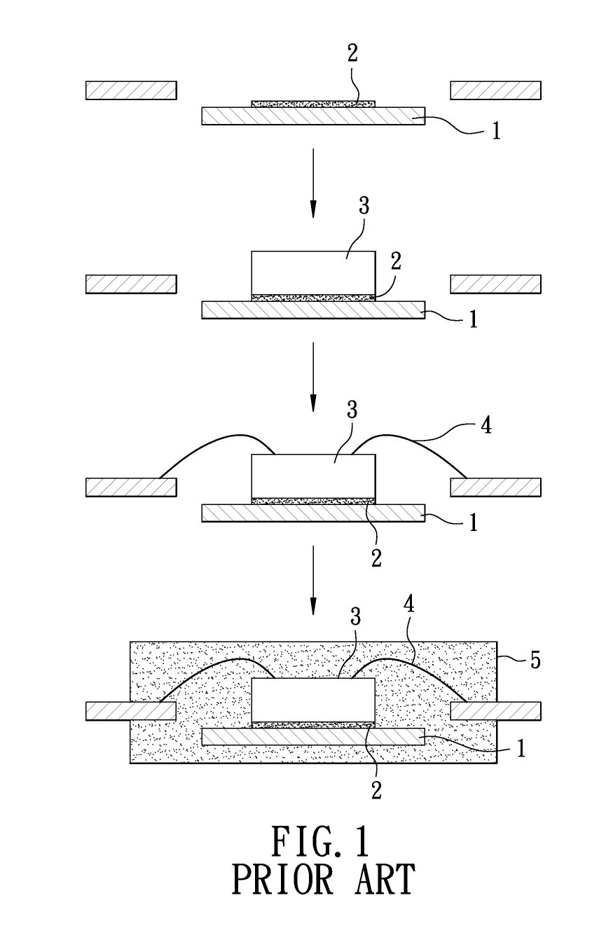

FIG. 2 is a flow chart of a preferred embodiment of this invention;

FIG. 3 is a schematic view illustrating the flow of preferred embodiment of this invention;

FIG. 4 is a schematic view illustrating another embodiment of this invention;

FIG. 5 is a schematic view illustrating a further embodiment of this invention;

FIG. 6 is a schematic view illustrating a next embodiment of this invention;

FIG. 7 is a schematic view illustrating one more embodiment of this invention;

### DETAILED DESCRIPTION OF THE PREFERRED EMBODIMENTS

Now, the present invention will be described more specifically with reference to the following embodiments. It is to be noted that the following descriptions of preferred embodiments of this invention are presented herein for purpose of illustration and description only; it is not intended to be exhaustive or to be limited to the precise form disclosed.

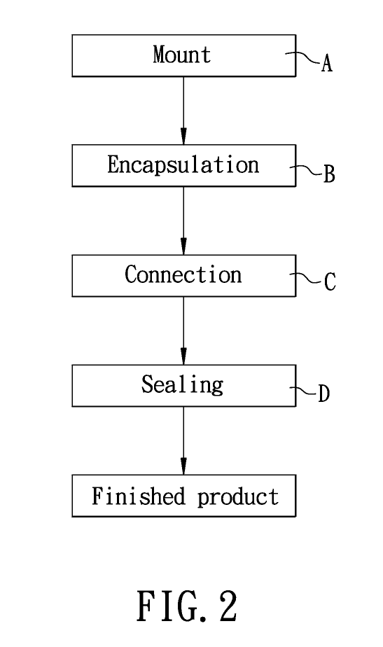

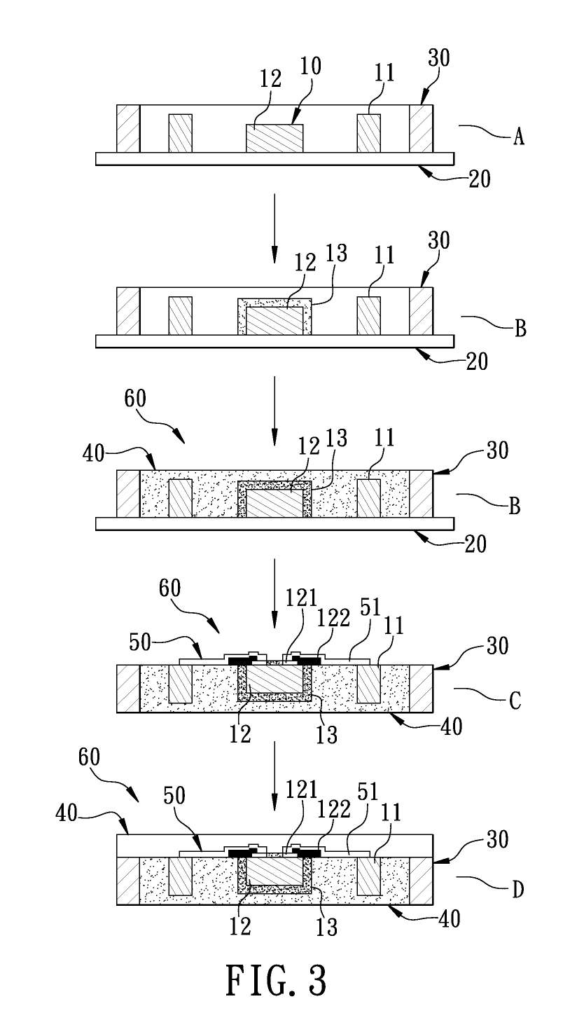

With reference to FIGS. 2 and 3 illustrating a preferred embodiment, a procedure of encapsulating an electronic component is provided in this invention, comprising the following steps.
A. Mount: a chipset 10 provided with a conductor 11 and a chip 12 are temporarily mounted on a carrier 20 movable, in which the carrier 20 may be formed with an adhesive material or the conductor 11 and the chip 12 is made to be adhered onto the carrier 20 or firmly mounted on a predetermined position of the carrier 20 for fear of displacement; further, outward around the chipset 10 mounted on the carrier 20, a hollow frame 30 is provided in a predetermined shape for control or is provided in a predetermined shape in the manner of cutting or another modeling; in this embodiment, the chip is a light-emitting component that may be a circuit unit necessarily encapsulated into an integrated circuit, a passive component and the like.
B. Encapsulation: a functional colloid 13 is made to adhere to the chip 12 that is a fluorescent colloid in this invention making the chip 12 bring a predetermined color, or that may be another colloid, such as a heat dissipation colloid; after the fluorescent colloid is solidified, a pre-encapsulated colloid 40 is made to adhere to the carrier 20 and filled into the frame 30; after the colloid 40 firmly adheres with the chipset 10, the carrier 20 is removed, thereby the encapsulated frame 30 in the shape being formed; the chip 12 and the conductor 11 may fully be adhere to and may be solidified inside the colloid 40 or may be partially exposed to the colloid 40 depending on the actual use.
C. Connection: a conduction portion 50 is provided between contact points 121 formed from the conductor 11 to the chip 12, which is a conductive glue 51 in this invention, in order to make the conductor 11 conductive to the chip 12; besides, an insulated colloid layer 122 may be spread around the contact 121 of the chip 12 for fear of a short circuit of the chip 12; the conductive portion 50 may also be connected to the contact points 121 from the conductor 11 to the chip 12 with a bonding wire or in another manner of connection.
D. Sealing: a side of the conductive portion 50 on the chip 12 is further formed with the functional glue 13 that is also a fluorescent colloid spread thereby around the chip 12, and the colloid 40 is formed at the side, thereby a sealed unit 60 being formed outside the chip 12 and the conductor 11; the chip 12 and the conductor 11 may alternatively be unsealed, if possible, and in the meantime, at step B for encapsulation, the chip 12 and the conductor 11 do not fully adhere to the colloid 40 and may sealed again with the colloid 40.

In order to further make apparent the structural features, applied skill and manners, and expected effects according to this invention, what are applied in this invention are in detail described, and it is thus believed that this invention is thoroughly and concretely apparent.

With reference to FIG. 3, in the modeled unit 60, the chip 12 and the conductor 11 are directly mounted and sealed with no substrate but the colloid 40 in order to save the costs of substrate design and use and decrease the cost of production. Further, after the chip 12 is packaged with the colloid 40, the thermal expansion causing the chip 12 to deform may be received directly by the colloid 40, and the circuit of the unit 60 is not easily open due to the heat deformation, thereby making the reliability and service life of the chip 60 increase. Next, the unit 60 is encapsulated with only the colloid 40, so its light-emitting area is not blocked, and the chip 12 may be given a light-emitting effect of complete period for a better light-emitting capability.

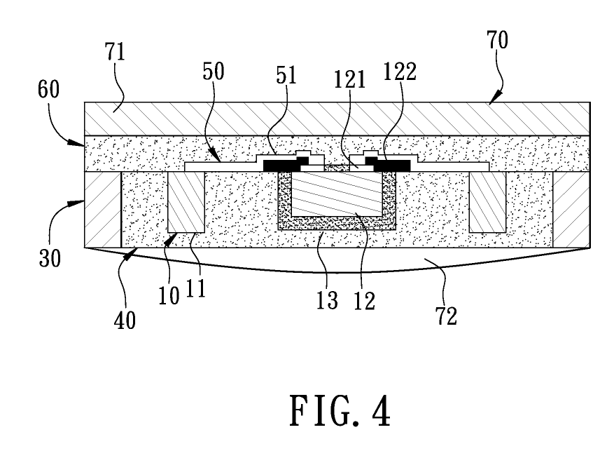

With reference to FIG. 4, in this invention, another embodiment illustrating the procedure of packaging the electronic component is provided, and the embodiment is the same in a major function as the previous embodiment, so unnecessary details are not given here, in which at a side of the colloid 40 of the unit 60, an active region 70, such as a reflecting plate 71 that makes the chip 12 when serving as a light-emitting component reflect, or a diffusion film that makes the chip diffuse the light, may be added, in which the active region 70 may be differently structured depending on an actual demand for achievement of various types of application.

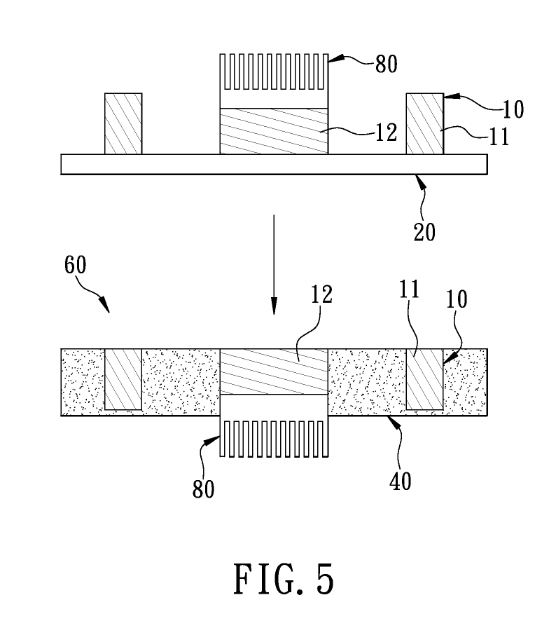

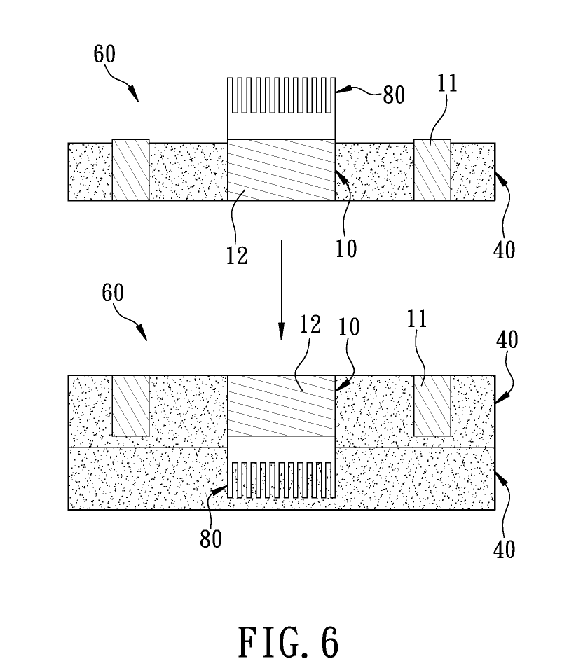

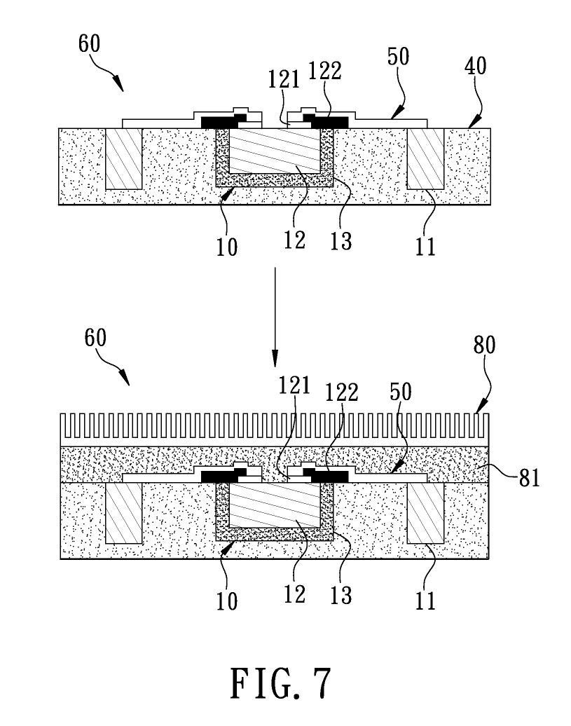

With reference to FIGS. 5, 6, and 7, a further embodiment illustrating the procedure of packaging the electronic component is provided, and the embodiment is the same in a major function as the previous embodiment, so unnecessary details are not given here, in which a heat dissipation device 80 is provided at a predetermined site of the chip 11. With reference to FIG. 5, the heat dissipation device 80 may be mounted onto the chip 12 before the step of encapsulation, and the chip 11 and the heat dissipation 80 are directly adhered at the step of encapsulation. Or with reference to FIG. 6, after being encapsulated, the chip 12 is not yet partially arranged inside the colloid 40, and after being combined with the chip 12, the heat dissipation device 80 is adhered and sealed so that the device 80 may also be mounted and adhered onto the chip 12. With reference to FIG. 7, after the connection of a conductive portion 50 of the unit 60, the heat dissipation device 80 may also be arranged with a heat dissipation colloid 81 for the effects of sealing and heat dissipation.

Here, the features and attainable expected effects of this invention are described again below:
1. In the procedure of packaging the electronic component according to this invention, when the unit is modeled, the substrate is not required, thereby the costs of substrate design and use being decreased.
2. In the procedure of packaging the electronic component according to this invention, when the unit is modeled, the chip does not contact the substrate, thereby no consideration of heat expansion between the substrate and the chip being made.
3. In the procedure of packaging the electronic component according to this invention, when the unit is modeled, what is formed around the chip is the colloid; for example, when the chip is a light-emitting component, its light-emitting unit may give out light in a complete period for increasing the coverage of visible light; the functional layers around formed may also bring a better light-emitting effect after the unit is encapsulated.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A procedure of packaging an electronic component, comprising at least the following steps:
A. Mount: a conductor and a chip being temporarily mounted on a carrier removable; and
B. Encapsulation: the colloid being adhered to the carrier, and after being adhered with colloid and mounted, the conductor and the chip being removed from the carrier, thereby a unit being formed.

2. The procedure of packaging the electronic component according to claim 1, wherein the chip is spread with a functional colloid and then encapsulated.

3. The procedure of packaging the electronic component according to claim 2, wherein the functional colloid is a fluorescent colloid.

4. The procedure of packaging the electronic component according to claim 1, wherein the procedure further comprises the following step:
c. Connection: contact points of the conductor chip in the unit being connected to each other with a conductive portion.

5. The procedure of packaging the electronic component according to claim 4, wherein the conductive portion is a conductive glue.

6. The procedure of packaging the electronic component according to claim 5, wherein an insulated layer is spread around the contact point of the chip before the conductive glue is spread.

7. The procedure of packaging the electronic component according to claim 4, wherein the conductive portion is connected with a bonding wire.

8. The procedure of packaging the electronic component according to claim 4, wherein the procedure next comprises the following step:
Sealing: a portion where the conductor and chip in the unit are not completely sealed being encapsulated with the colloid.

9. The procedure of packaging the electronic component according to claim 8, wherein the chip is spread with a functional glue and then sealed.

10. The procedure of packaging the electronic component according to claim 9, wherein the functional glue is a fluorescent colloid.

11. The procedure of packaging the electronic component according to claim 1, wherein a hollow frame provided with a predetermined outline is arranged on the carrier and the unit is formed in the frame in a predetermined shape.

12. The procedure of packaging the electronic component according to claim 1, wherein a heat dissipation device is provided on the chip.

13. The procedure of packaging the electronic component according to claim 1, wherein an active region is formed at the outside of the unit.

14. The procedure of packaging the electronic component according to claim 13, wherein the active region is a reflective plate.

15. The procedure of packaging the electronic component according to claim 13, wherein the active region is a diffusion film.

16. The procedure of packaging the electronic component according to claim 1, wherein the chip is a light-emitting component, an integrated circuit, a passive component or the like as a circuit unit that must be packaged.

17. The procedure of packaging the electronic component according to claim 1, wherein the chip and the conductor are separately provided on the carrier.
